(19) United States
(12) Patent Application Publication
(10) Pub. No.: US 2016/0141287 A1
(43) Pub. Date: May 19, 2016

(54) ELECTROSTATIC DISCHARGE PROTECTION CIRCUIT, STRUCTURE AND METHOD OF MAKING THE SAME

(71) Applicant: MACRONIX International Co., Ltd., Hsinchu (TW)

(72) Inventors: Chieh-Wei He, Hsinchu (TW); Qi-An Xu, Jiangsu (CN); Jun-Jun Yu, Jiangsu (CN); Han Hao, Jiangsu (CN)

(21) Appl. No.: 14/595,753

(22) Filed: Jan. 13, 2015

(30) Foreign Application Priority Data
Nov. 13, 2014 (CN) 201410640008.4

(51) Int. Cl. H01L 27/02; H01L 49/02; H01L 21/8249; H01L 27/06

(52) U.S. Cl. CPC H01L 27/0266; H01L 27/0262; H01L 27/0288; H01L 27/0255; H01L 27/0635; H01L 28/20; H01L 21/8249

(57) ABSTRACT

An ESD structure, including a first conductive type substrate, a second conductive type well region in the substrate, first/second doped regions (the first type), fourth to sixth doped regions (second conductive type), and first/second gates, is provided. The first/second doped regions are respectively disposed in the well region and the substrate. The first/second gates are on the substrate surface with no well region below. A third doped region is between the first and second gates in the substrate. The fourth doped region is in the substrate and on one side of the first/second gates. The fifth doped region is in the substrate, extends into the well region, and on another side of the first/second gates. The first doped region is located between the fifth and sixth doped region. The first/sixth doped regions and the first gate are connected. The fourth/second doped region and the second gate are connected.

This application claims the priority benefit of China application serial no. 201410640008.4, filed on Nov. 13, 2014. The entirety of the above-mentioned patent application is hereby incorporated by reference herein and made a part of this specification.

### BACKGROUND OF THE DISCLOSURE

1. Field of the Disclosure

The disclosure relates to an electrostatic discharge protection circuit, an electrostatic discharge protection circuit structure, and a manufacturing method thereof.

2. Description of Related Art

Electrostatic discharge (ESD) is a phenomenon that charges are accumulated in a non-conductor or a conductor that is not grounded, and then rapidly discharged through a discharge path in a short period of time. Electrostatic discharge damages circuits in the integrated circuits. Human bodies, machines packaging the integrated circuits, or instruments testing the integrated circuits are common charge-carrying entities. When the charge-carrying entities contact a chip, the charges are charged into the chip. An instantaneous power of the electrostatic discharge may damage or disable the integrated circuits in the chip.

FIG. 1 is a cross-sectional view illustrating a layout of a conventional electrostatic discharge protection circuit, and FIG. 2 is an equivalent circuit diagram of the conventional electrostatic discharge protection circuit shown in FIG. 1. As shown in FIG. 1, an electrostatic discharge protection circuit 100 suitable for a high voltage input is formed on a P-type substrate 102. A P+ doped region 104 and an N+ doped region 106 forming a diode D2 (see FIG. 2) and N+ doped regions 114, 116, and 118 forming cascade MOS transistors M1 and M2 are forming on the substrate 102. In addition, the P+ doped region 104 is further connected to a pad PAD, while the P-type substrate is further connected to a ground terminal GND through the P+ doped region 120.

In the circuit configuration shown in FIGS. 1 and 2, a double guard ring, namely a N+ doped region 110 and a P+ doped region 112, needs to be additionally disposed between the diode D2 and the cascade NMOS to prevent a latch-up effect. The double guard ring is at least 20 μm to separate the diode D2 and the cascade NMOS. In addition, a reverse diode D1 (see FIG. 2, not shown in FIG. 1) sometimes needs to be additionally disposed. However, disposing the double guard ring significantly increases a layout area of the electrostatic protection circuit. Also, the additional reverse diode D1 also significantly increases the layout area of the electrostatic protection circuit. In addition, under the conventional configuration, a second breakdown current thereof is approximately 7.1 mA/μm. Namely, the electrostatic discharge protection performance is less than preferable.

Thus, how to design an electrostatic discharge circuit having a smaller area while effectively improving the performance of electrostatic discharge protection is an issue to be worked on in this field.

### SUMMARY OF THE DISCLOSURE

The disclosure provides an electrostatic discharge protection circuit having a reduced size and provide a preferable electrostatic discharge protection effect.

According to an embodiment of the disclosure, an electrostatic discharge protection structure is provided. The electrostatic discharge protection structure includes: a substrate having a first conductive type, a well region having a second conductive type and disposed in the substrate, a first doped region having the first conductive type and disposed in the well region; a second doped region having the first conductive type and disposed in the substrate, a first gate and a second gate respectively disposed on regions of the substrate where the well region is not disposed, a third doped region having the second conductive type, disposed in the substrate, and located between the first gate and the second gate, a fourth doped region having the second conductive type, disposed in the substrate, located on one side of the first gate and the second gate, and adjacent to the second doped region, a fifth doped region having the second conductive type, disposed in the substrate, extending into the well region, and located on another side of the first gate and the second gate, and a sixth doped region having the second conductive type, disposed in the well region, and making the first doped region located between the fifth doped region and the sixth doped region. In addition, the first doped region, the sixth doped region, and the first gate are electrically connected to a first pad, and the fourth doped region, the second doped region, and the second gate are electrically connected to a second pad.

According to an embodiment of the disclosure, the electrostatic discharge protection structure further includes a resistor disposed between the second gate and the second pad. Also, according to an embodiment of the disclosure, the first pad is an input pad, and the second pad is a ground pad. Also, according to an embodiment of the disclosure, a first bipolar junction transistor is formed by the first doped region, the well region, and the substrate, and a second bipolar junction transistor is formed by the well region, the substrate, and the fourth doped region. A silicon controlled rectifier is formed by the first bipolar junction transistor and the second bipolar junction transistor.

According to an embodiment of the disclosure, the first conductive type is P-type and the second conductive type is N-type.

The disclosure further provides a manufacturing method of an electrostatic discharge protection structure, including: providing a substrate having a first conductive type; forming a well region, wherein the well region has a second conductive type and is disposed in the substrate; forming a first doped region having the first conductive type in the well region; forming a second doped region having the first conductive type in the substrate; forming a first gate and a second gate respectively disposed on regions of the substrate where the well region is not disposed; forming a third doped region having the second conductive type, and located in the substrate and between the first gate and the second gate; forming a fourth doped region having the second conductive type, located in the substrate and on one side of the first gate and the second gate, and adjacent to the second doped region; forming a fifth doped region having the second conductive type, located in the substrate, extending into the well region, and located on another side of the first gate and the second gate; forming a sixth doped region having the second conductive type, located in the well region, and making the first doped region located between the fifth doped region and the sixth doped region; electrically connecting the first doped region, the sixth doped region, and the first gate to a first pad, and electrically connecting the fourth doped region, the second doped region, and the second gate to a second pad.

According to an embodiment of the disclosure, the method further includes forming a resistor between the second gate and the second pad. In addition, the first pad is an input pad, and the second pad is a ground pad. Moreover, the first conductive type may be P-type, and the second conductive type may be N-type.

The disclosure further provides an electrostatic discharge protection circuit, including: a first pad and a second pad, a first MOS transistor having a first gate, a first source/drain terminal, and a common source/drain terminal, a second MOS transistor, having a second gate, a second source/drain terminal, and the common source/drain terminal, a first bipolar junction transistor, having an emitter coupled to the first pad, a base coupled to the first source/drain terminal of the first MOS transistor, and a collector coupled to the second pad, and a second bipolar junction transistor, having an emitter coupled to the second pad, a base coupled to the collector of the first bipolar junction transistor and the second pad, and a collector coupled to the base of the first bipolar junction transistor and the first source/drain terminal of the first MOS transistor. In addition, the first gate is coupled to the first pad, the second gate is coupled to the second pad, the second source/drain terminal is coupled to the second pad, and the first MOS transistor and the second MOS transistor are serially connected by the common source/drain terminal.

According to an embodiment of the disclosure, the electrostatic discharge protection circuit further includes a first resistor coupled between the second gate of the second MOS transistor and the second pad, a second resistor, coupled between the first source/drain terminal of the first MOS transistor and the first pad, and a third resistor coupled between the collector of the first bipolar junction transistor and the second pad. According to an embodiment of the disclosure, the electrostatic discharge protection circuit further includes a diode coupled between the first pad and the second pad. The first pad may be an input pad, and the second pad may be a ground pad.

Based on the above, the electrostatic discharge protection circuit, the electrostatic discharge protection circuit structure, and the manufacturing method thereof according to the embodiments of the disclosure, which is a silicon controlled rectifying structure triggered by the cascade NMOS transistor, is capable of effectively releasing the electrostatic discharge and significantly improving the performance of the electrostatic discharge protection circuit.

In addition, since the double guard ring and the reverse diode are not required, the layout area may be reduced by multiple times compared with the conventional structure.

In order to make the aforementioned and other objects, features and advantages of the disclosure more comprehensible, embodiments accompanied with figures are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a cross-sectional view illustrating a layout of a conventional electrostatic discharge protection circuit.

FIG. 2 is an equivalent circuit diagram of the conventional electrostatic discharge protection circuit shown in FIG. 1.

FIG. 3 is a cross-sectional view of an electrostatic discharge protection circuit according to an embodiment of the disclosure.

FIG. 4 is an equivalent circuit diagram corresponding to the electrostatic discharge protection circuit shown in FIG. 3.

FIG. 5 is a current-voltage diagram illustrating a test result of an electrostatic discharge protection circuit according to an embodiment of the disclosure.

FIGS. 6A, 6B, 6C are diagrams showing test results of turn-on speed of the embodiments of the disclosure and the conventional structures.

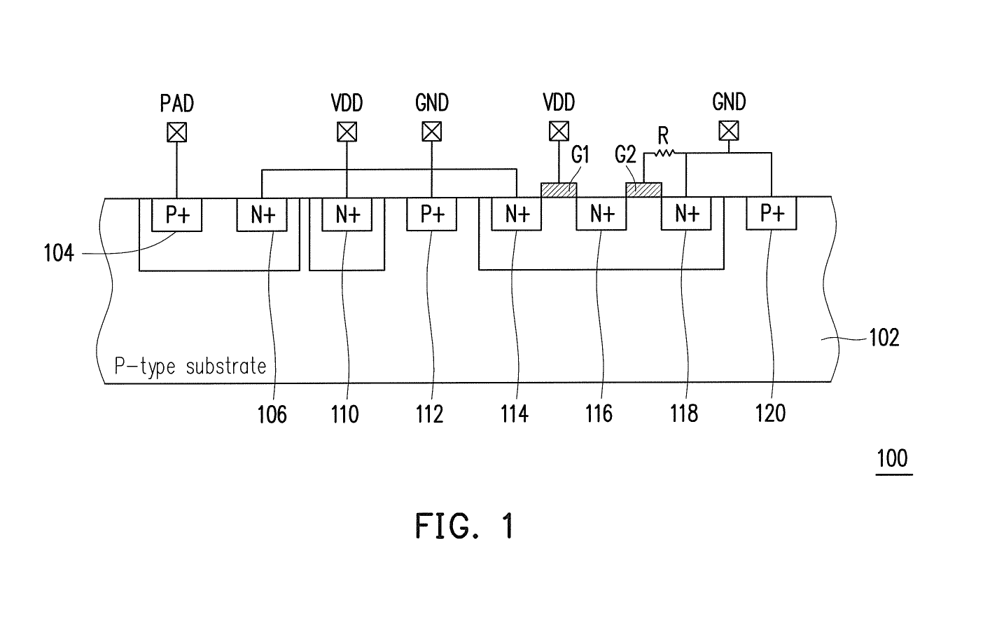

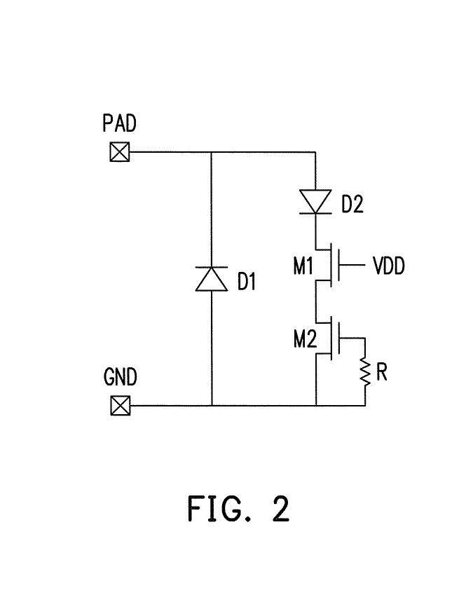

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

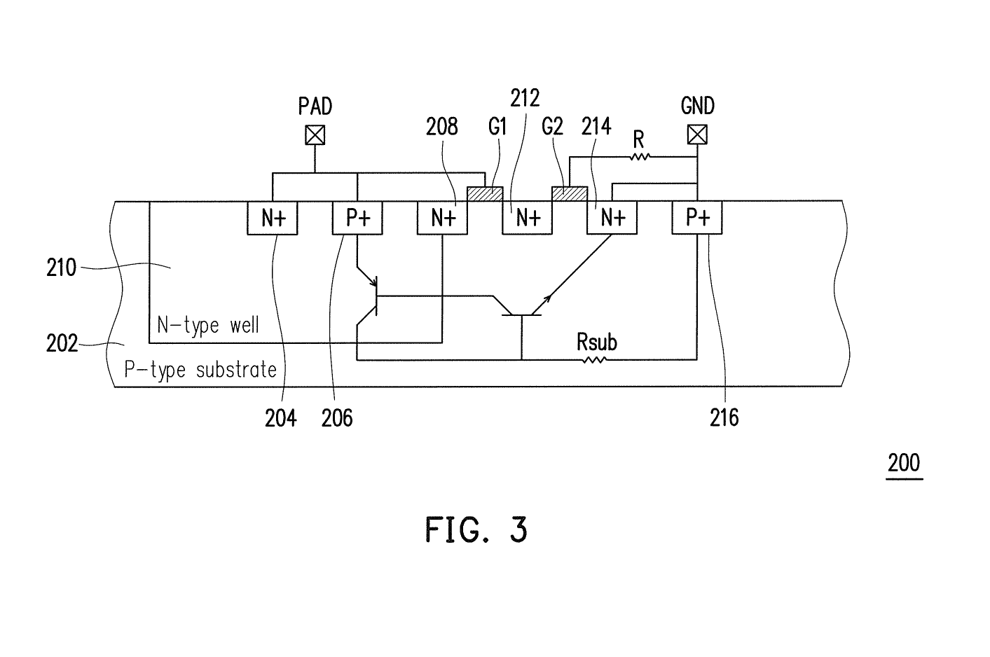

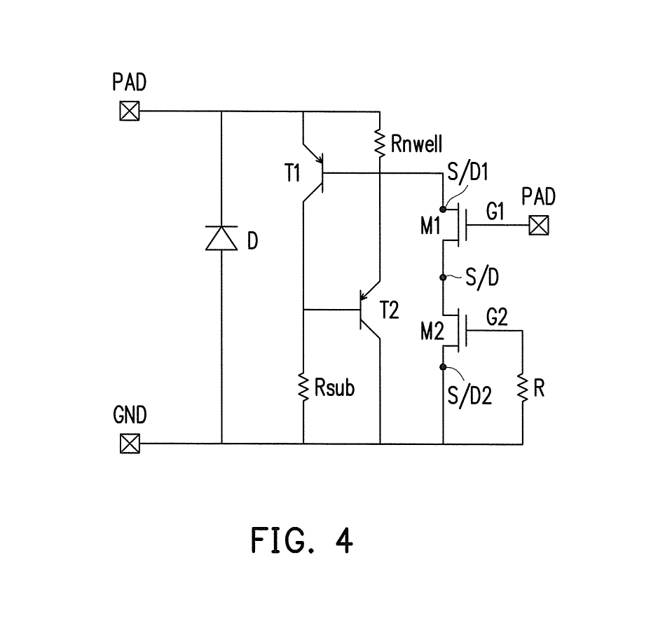

FIG. 3 is cross-sectional view illustrating a metal oxide semiconductor device according to an embodiment of the disclosure. The metal oxide semiconductor device is an electrostatic discharge protection circuit. FIG. 4 is an equivalent circuit diagram corresponding to FIG. 3. The electrostatic discharge protection circuit of this embodiment is suitable to be an electrostatic discharge protection circuit of a high voltage input pad.

Referring to FIG. 3, an electrostatic discharge protection circuit 200 includes a substrate 202 and a well region 210 disposed in the substrate 202. The well region 210 has a conductive type different from a conductive type of the substrate, for example. In this embodiment, a dopant of the substrate 202 is of a first conductive type, such as a P-type dopant (the substrate is referred to as the P-type substrate 202 hereinafter). A dopant of the well region 210 is of a second conductive type. In this embodiment, the dopant of the well region 210 is a N-type dopant (the well region is referred to as the N-type well region 210 hereinafter). In addition, it shall be understood that the description of the N-type well region 210 and the P-type substrate 202 in the embodiment is merely for easy comprehension, instead of limiting the embodiment of the disclosure. People skilled in the art understand that the embodiment may be appropriately modified, the conductive types of P-type and N-type may be appropriately modified, and a configuration of an overall structure and the conductive types of dopant may be correspondingly modified as well.

As shown in FIG. 3, the P-type substrate 202 of the electrostatic discharge protection circuit 200 further includes a first doped (P+) region 206, a second doped (P+) region 216, a third doped (N+) region 212, a fourth doped (N+) region 214, a fifth doped (N+) region 208 and a sixth doped (N+) region 204. In addition, a first gate G1 and a second gate G2 are further included on the surface of the P-type substrate 202.

In this embodiment, the first doped region 206 has the first conductive type, namely P-type, for example, and is disposed in the N-type well region 210. The second doped region 216 also has the first type (P-type) and is disposed in the P-type substrate 202. The first gate G1 and the second gate G2 are respectively disposed on a surface of the P-type substrate 201 where the N-type well region 210 is not disposed. The third doped region 212 has the second conductive type, namely N-type, and is disposed in the P-type substrate 202 and located between the first gate G1 and the second gate G2. The fourth doped region 214 has the second conductive type, namely N-type, and is disposed in the P-type substrate 202, located on one side of the first gate G1 and the second gate G2, and adjacent to the second doped (P+) region 216. The fifth doped region 208 also has the second conductive type, namely N-type, and is disposed in the P-type substrate 202 and extends into the N-type well region 210. In addition, the fifth doped region 208 is located on another side of the first gate G1 and the second gate G2.

Moreover, the sixth doped region 204 also having the second conductive type (namely N-type) is disposed in the N-type well region 210, making the first doped (P+) region 206 located between the fifth doped (N+) region 208 and the sixth doped (N+) region 204.

In addition, the first doped (P+) region 206, the sixth doped (N+) region 204, and the first gate G1 are electrically connected to a first pad PAD. The first pad PAD may receive an input voltage, for example. Namely, when an electrostatic discharge event occurs, the electrostatic discharge may enter the electrostatic discharge protection circuit 200 through the first pad PAD. In addition, the fourth doped (N+) region 214, the second doped (P+) region 216, and the second gate G2 are electrically connected to a second pad GND generally functioning as a ground terminal.

In the structure, a first NMOS transistor M1 is formed by the first gate G1, the third doped (N+) region 212, and the fifth doped (N+) region 208. The third doped (N+) region 212 and the fifth doped (N+) region 208 serve as source/drain terminals of the first NMOS transistor M1. Moreover, a second NMOS transistor M2 is formed by the second gate G2, the third doped (N+) region 212, and the fourth doped (N+) region 214. The third doped (N+) region 212 and the fourth doped (N+) region 214 serve as source/drain terminals of the second NMOS transistor M2. The third doped (N+) region 212 is a common terminal of the first NMOS transistor M1 and the second NMOS transistor M2, thereby forming a cascade MOS transistor configuration.

In addition, the first doped (P+) region 206, the N-type well 210, and the P-type substrate 202 form an emitter, a base, and a collector of a first bipolar junction transistor T1. The fourth doped (N+) region 214, the P-type substrate 202, and the N-type well 210 form an emitter, a base, and a collector of a second bipolar junction transistor T2. In this way, the first and second bipolar junction transistors T1 and T2 form a silicon controlled rectifier SCR.

In addition, a well region resistor Rnwell is formed in the N-type well region 210, and a substrate resistor Rsub is formed in the P-type substrate. In addition, a resistor R may be disposed between the second pad GND and the second gate G2 if required.

Also, the P-type substrate 202 and the N-type well 210 form a parasitic reverse diode D. Therefore, unlike the conventional technology, a reverse diode needs not be additionally disposed in this embodiment.

An operation of the electrostatic discharge protection circuit of this embodiment is described in the following. An equivalent circuit diagram of this embodiment is shown in FIG. 4. The equivalent circuit diagram of this embodiment basically includes the silicon controlled rectifier SCR formed by the first and second ambipolar transistors T1 and T2, and a cascade NMOS formed by the first and second NMOS transistors M1 and M2.

Then, the equivalent circuit diagram of this embodiment and an operation thereof are described with reference to FIGS. 3 and 4. As shown in FIG. 4, FIG. 4 is an equivalent circuit diagram of the electrostatic discharge protection circuit of FIG. 3. According to FIG. 4, the electrostatic discharge protection circuit at least includes the silicon controlled rectifying circuit SCR and the cascade NMOS circuit. The silicon controlled rectifying circuit SCR and the cascade NMOS are connected between the first pad PAD and the second pad GND (as the ground terminal in this embodiment).

The silicon controlled rectifying circuit SCR includes the first bipolar junction transistor T1 (PNP structure) and the second bipolar junction transistor T2 (NPN structure). In addition, the emitter of the first bipolar junction transistor T1 is coupled to the first pad PAD, the collector thereof is coupled to the second pad GND through the resistor Rsub, and the base thereof is coupled to the collector of the second ambipolar transistor T2. The resistor Rsub is a substrate resistor as shown in FIG. 3. In addition, the base of the second bipolar transistor T2 is coupled to the collector of the first bipolar junction transistor T1, and is coupled to the second pad GND through the resistor Rsub.

The cascade NMOS circuit includes the first NMOS transistor M1 and the second NMOS transistor M2. The first NMOS transistor M1 has a source/drain terminal S/D1, a common source/drain terminal S/D, and the first gate G1. The second NMOS transistor M1 has a source/drain terminal S/D2, the common source/drain terminal S/D, and the second gate G2. The first NMOS transistor M1 and the second NMOS transistor M2 are serially connected through the common source/drain terminal S/D. The first gate G1 of the first NMOS transistor M1 is coupled to the first pad PAD. The second gate G2 of the second NMOS transistor M2 is coupled to the second pad GND. In addition, the source/drain terminal S/D1 of the first NMOS transistor M1 is coupled to the base of the first bipolar transistor T1, and the source/drain terminal S/D2 of the second NMOS transistor is coupled to the emitter of the second bipolar transistor T2 and the second pad GND. In this embodiment, the NMOS transistor is described herein as an example. However, people skilled in the art may modify the NMOS transistor into a PMOS transistor or a similar component. Of course, other corresponding parts need to be correspondingly modified as well, and no further details in this regard will be described below.

Moreover, in another embodiment, the second gate G2 of the second NMOS transistor M2 may be connected to the second pad GND through the resistor R. In addition, the resistor Rnwell may be formed in the N-type well region 210.

In the operation, as shown in FIG. 3, since the sixth doped (N+) region 204 and the first doped (P+) region 206 are connected to the first pad PAD together, the two components have an equal potential. Therefore, when there is an electrostatic discharge event and a high voltage is applied to the first pad PAD, the sixth doped (N+) region 204 and the first doped (P+) region 206 have a substantially equal potential without a voltage difference. Therefore, no forward bias is occurred between the sixth doped (N+) region 204 and the first doped (P+) region 206. Namely, at this time, the first bipolar junction transistor T1 shown in FIG. 4 is not turned on. In other words, the silicon controlled rectifier SCR is not easily triggered to function at an initial moment when the electrostatic discharge event occurs.

When the electrostatic discharge event occurs, the voltage applied to the first pad PAD will turn on the first NMOS transistor M1 and the second NMOS transistor M2 of the cascade MOS. Here, the first NMOS transistor M1 and the second NMOS transistor M2 being turned on provides a discharge current path, such that an electrostatic discharge current flows from the first pad PAD to the second pad GND through the first NMOS transistor M1 and the second NMOS transistor M2. In other words, as shown in FIG. 3, a discharging path from the first pad PAD to the second pad GND (ground) through the N-type well region 210, the P-type substrate 202, and the second doped (P+) region 216 is provided at this time.

When the cascade MOS transistor is conductive, the voltage on the first pad PAD drops accordingly. Thus, a voltage difference between the sixth doped (N+) region 204 and the first doped (P+) region 206 is generated. The forward bias will turn on the first bipolar junction transistor T1, and the second bipolar junction transistor T2 is thus turned on as well. Namely the, the silicon controlled rectifier SCR starts to operate to provide an electrostatic discharging path. In other words, as shown in FIG. 3, a discharging path from the first pad PAD to the second pad GND (ground) through the N-type well region 210, the P-type substrate 202, and the second doped (P+) region 216 is provided at this time.

Under the structure of the embodiment, since the MOS part needs to be turned on to subsequently trigger the silicon controlled rectifying circuit SCR; a holding voltage of the MOS may be increased. In addition, since the structure of the embodiment mainly uses the silicon controlled rectifying circuit SCR, the cascade MOS with a large area is not required. In addition, since the silicon controlled rectifying circuit SCR is generally not large in size; an area occupied by the electrostatic discharge protection circuit of this embodiment may be further reduced. Namely, the electrostatic discharge protection circuit/structure according to this embodiment not only provides an excellent electrostatic discharge protection, but reduces the area occupied by the electrostatic discharge protection circuit.

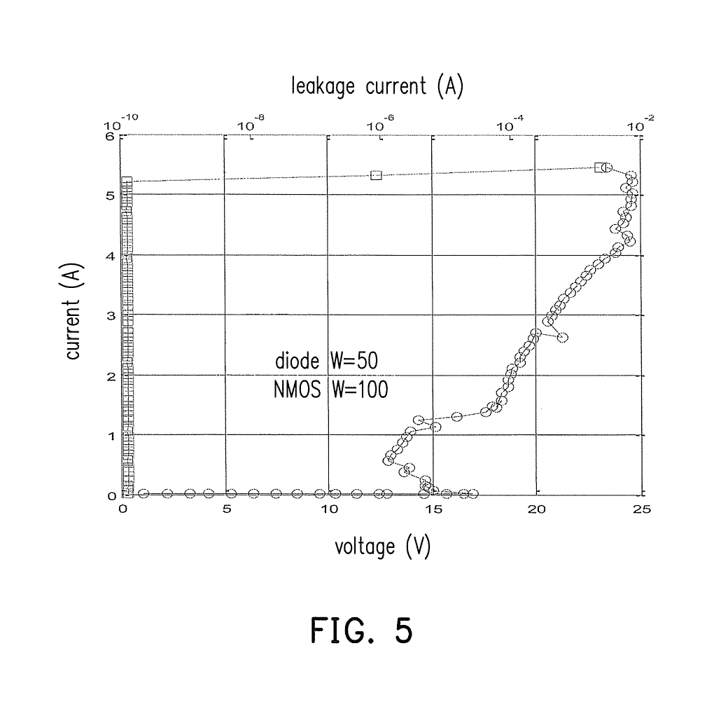

FIG. 5 is a current-voltage diagram illustrating a test result of an electrostatic discharge protection circuit according to an embodiment of the disclosure. The test is performed by using a transmission line pulse (TLP). As shown on the test result, values of trigger voltage and current (it₁, vt₁)=(0.017977, 16.9358), second breakdown current and voltage (it₂, vt₂)=(5.3209, 24.5672), and holding current and voltage (itₕ, vtₕ)=(0.56639, 12.8665) are obtained.

Based on the result above, it is indicated that under the configuration of this embodiment, the holding voltage vtₕ may reach 12.8665V, higher than that of the conventional electrostatic discharge protection circuit. In addition, the second breakdown current it₂ also reaches 53.2 mA/μm, higher than 7.1 mA/μm of the conventional electrostatic discharge protection circuit by multiple times. Thus, the configuration of this embodiment provides an excellent electrostatic discharge protection.

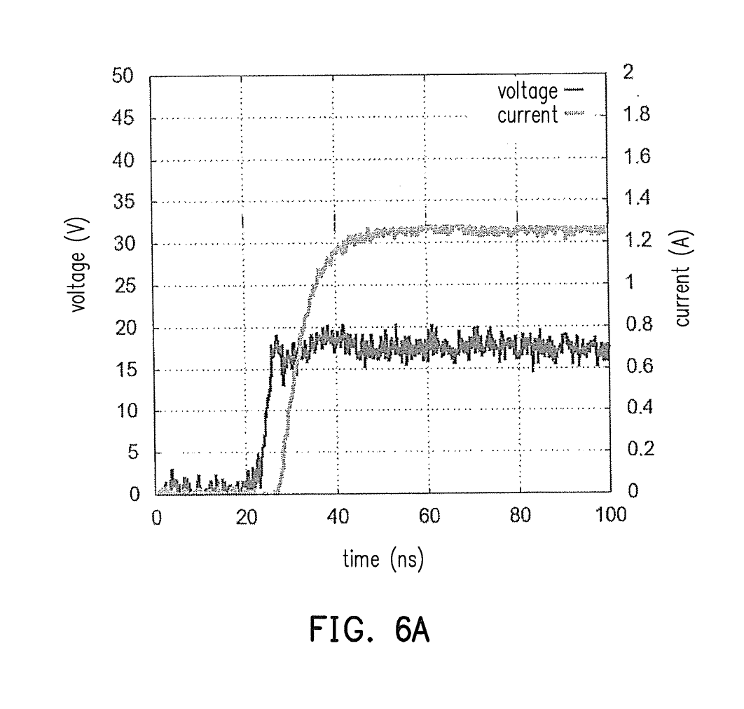

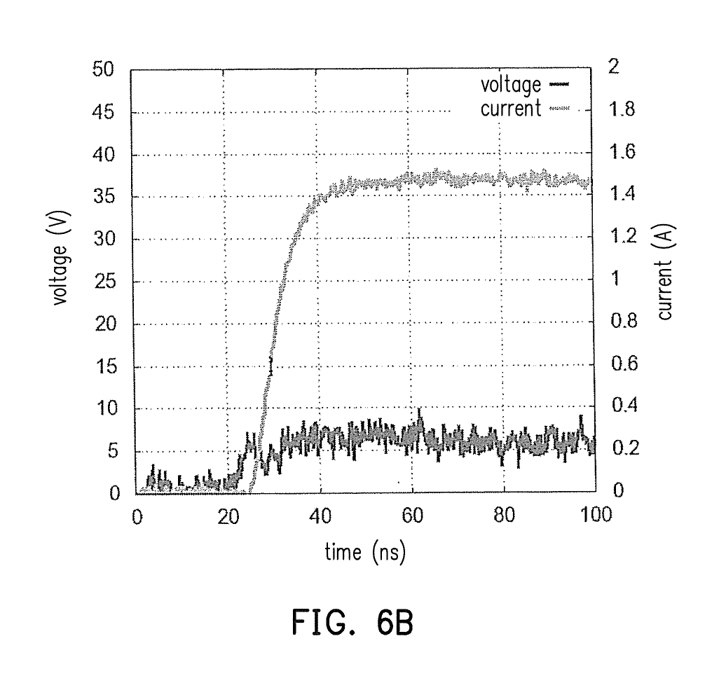

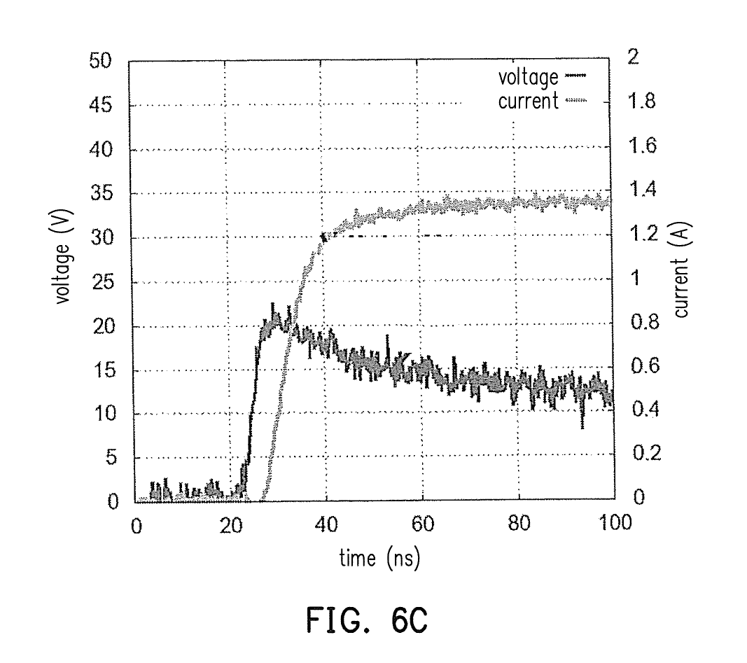

FIGS. 6A, 6B, 6C are diagrams showing test results of turn-on speeds of the embodiments of the disclosure and the conventional structures. FIG. 6A is a diagram illustrating a result of a speed of conduction of this embodiment. FIGS. 6B and 6C are diagrams illustrating results of turn-on speeds of test keys PMSCR and MD NMOS for comparison. Under a 40V TLP test, FIG. 6B shows that even though changes of voltage and current are stable, a conduction speed is slower. FIG. 6C shows that the voltage becomes unstable through time. On the contrary, FIG. 6A shows that under the same test condition, the test result of this embodiment is very stable, and the turn-on speed thereof is very quick.

In addition, a manufacturing method of an electrostatic discharge protection circuit is provided according to another embodiment of the disclosure. As shown in FIG. 3, the substrate 202 is provided first, and the substrate 202 may be a P-type substrate in this embodiment.

Then, a well region, such as the N-type well region 210, is formed in the P-type substrate 202. The first and second doped (P+) regions 206 and 216 are formed in the N-type well region 210 and the P-type substrate 202.

The first gate G1 and the second gate G2 are formed on a surface of the P-type substrate 202 where the N-type well region 210 is not disposed. The third doped (N+) region 212, the fourth doped (N+) region 214, and the fifth doped (N+) region 208 are formed in the P-type substrate 202. The third doped (N+) region 212 is formed in the P-type substrate 202 and located between the first gate G1 and the second gate G2. The fourth doped (N+) region 214 is formed in the P-type substrate 202, located on one side of the first gate G1 and the second gate G2, and adjacent to the second doped (P+) region 216. The fifth doped (N+) region 208 is formed in the P-type substrate 202 and extends into the N-type well region 210. In addition, the fifth doped region 208 is located on another side of the first gate G1 and the second gate G2.

The sixth doped (N+) region 204 is formed in the N-type well region 210. The sixth doped region 204 is located in the N-type well region 210 and makes the first doped (P+) region 206 located between the fifth doped (N+) region 208 and the sixth doped (N+) region 204.

Then, the first doped (P+) region 206, the sixth doped (N+) region 204, and the first gate G1 are electrically connected to the first pad PAD, and the fourth doped (N+) region 214, the second doped (P+) region 216, and the second gate G2 are electrically connected to the second pad GND.

The manufacturing method above only serves as an example for an illustrative purpose. Suitable semiconductor manufacturing processes, such as photolithography, ion implantation, and fog nation methods of a gate, etc. may also apply. In addition, a sequence of forming the doped regions is not fixed. Namely, any methods may apply, as long as the structure shown in FIG. 3 is formed.

In addition, the substrate, the first doped region, and the second doped region are exemplified as P-type, while the well region and other doped regions are exemplified as N-type. However, the above only serves as an example. People skilled in the art may appropriately modify the types of dopant based on practical needs.

In view of the foregoing, the disclosure provides the silicon controlled rectifying structure triggered by the cascade NMOS transistor capable of effectively releasing the electrostatic discharge, significantly improving the performance of the electrostatic discharge protection circuit, and reducing the layout area by multiple times.

For example, under the structure according to the embodiments of the disclosure, a double guard ring is not required between the diode and the cascade NMOS. Therefore, the layout area occupied by the guard ring in a conventional configuration is saved.

In addition, under the structure according to the embodiments of the disclosure, the reverse diode does not need to be designed. Instead, a parasitic diode forming by the P-type substrate (e.g., the P-type substrate 202 in FIG. 3) and the N-type well (e.g., the N-type well 210 in FIG. 3) may provide a preferable ESD protection. Thus, the layout area occupied by the conventional reverse diode is saved.

Accordingly, the electrostatic discharge protection structure according to the embodiments of the disclosure provides an excellent electrostatic discharge performance using a small layout area.

In addition, the electrostatic discharge circuit according to the embodiments of the disclosure may become turned on quickly when an electrostatic discharge event occurs. Thus, an effective electrostatic discharge protection is ensured.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. An electrostatic discharge protection structure, comprising:
a substrate, having a first conductive type;
a well region, having a second conductive type and disposed in the substrate;
a first doped region, having the first conductive type and disposed in the well region;
a second doped region, having the first conductive type and disposed in the substrate;
a first gate and a second gate, respectively disposed on a surface of the substrate where the well region is not disposed;
a third doped region, having the second conductive type, disposed in the substrate, and located between the first gate and the second gate;
a fourth doped region, having the second conductive type, disposed in the substrate, located on one side of the first gate and the second gate, and adjacent to the second doped region;
a fifth doped region, having the second conductive type, disposed in the substrate, extending into the well region, and located on another side of the first gate and the second gate; and
a sixth doped region, having the second conductive type, disposed in the well region, and making the first doped region located between the fifth doped region and the sixth doped region,
wherein the first doped region, the sixth doped region, and the first gate are electrically connected to a first pad, and
the fourth doped region, the second doped region, and the second gate are electrically connected to a second pad.

2. The electrostatic discharge protection structure as claimed in claim 1, further comprising a resistor disposed between the second gate and the second pad.

3. The electrostatic discharge protection structure as claimed in claim 1, wherein the first pad is an input pad, and the second pad is a ground pad.

4. The electrostatic discharge protection structure as claimed in claim 1, wherein a first bipolar junction transistor is formed by the first doped region, the well region, and the substrate, and a second bipolar junction transistor is formed by the well region, the substrate, and the fourth doped region.

5. The electrostatic discharge protection structure as claimed in claim 4, wherein a silicon controlled rectifier is formed by the first bipolar junction transistor and the second bipolar junction transistor.

6. The electrostatic discharge protection structure as claimed in claim 1, wherein the first conductive type is P-type, and the second conductive type is N-type.

7. A manufacturing method of an electrostatic discharge protection structure, comprising:
providing a substrate having a first conductive type;
forming a well region, wherein the well region has a second conductive type and is disposed in the substrate;
forming a first doped region having the first conductive type in the well region;
forming a second doped region having the first conductive type in the substrate;
forming a first gate and a second gate respectively disposed on a surface of the substrate where the well region is not disposed;
forming a third doped region having the second conductive type, and located in the substrate and between the first gate and the second gate;
forming a fourth doped region having the second conductive type, located in the substrate and on one side of the first gate and the second gate, and adjacent to the second doped region;
forming a fifth doped region having the second conductive type, located in the substrate, extending into the well region, and located on another side of the first gate and the second gate; and
forming a sixth doped region having the second conductive type, located in the well region, and making the first doped region located between the fifth doped region and the sixth doped region;
electrically connecting the first doped region, the sixth doped region, and the first gate to a first pad, and
electrically connecting the fourth doped region, the second doped region, and the second gate to a second pad.

8. The manufacturing method of the electrostatic discharge protection structure as claimed in claim 7, further comprising forming a resistor between the second gate and the second pad.

9. The manufacturing method of the electrostatic discharge protection structure as claimed in claim 7, wherein the first pad is an input pad, and the second pad is a ground pad.

10. The manufacturing method of the electrostatic discharge protection structure as claimed in claim 7, wherein the first conductive type is P-type, and the second conductive type is N-type.

11. An electrostatic discharge protection circuit, comprising:
a first pad and a second pad;
a first MOS transistor, having a first gate, a first source/drain terminal, and a common source/drain terminal, wherein the first gate is coupled to the first pad;
a second MOS transistor, having a second gate, a second source/drain terminal, and the common source/drain terminal, wherein the second gate is coupled to the second pad, the second source/drain terminal is coupled to the second pad, and the first MOS transistor and the second MOS transistor are serially connected by the common source/drain terminal;
a first bipolar junction transistor, having an emitter coupled to the first pad, a base coupled to the first source/drain terminal of the first MOS transistor, and a collector coupled to the second pad; and
a second bipolar junction transistor, having an emitter coupled to the second pad, a base coupled to the collector of the first bipolar junction transistor and the second pad, and a collector coupled to the base of the first bipolar junction transistor and the first source/drain terminal of the first MOS transistor.

12. The electrostatic discharge protection circuit as claimed in claim 11, further comprising:
a first resistor, coupled between the second gate of the second MOS transistor and the second pad;
a second resistor, coupled between the first source/drain terminal of the first MOS transistor and the first pad; and
a third resistor, coupled between the collector of the first ambipolar transistor and the second pad.

13. The electrostatic discharge protection circuit as claimed in claim 11, further comprising a diode coupled between the first pad and the second pad.

14. The electrostatic discharge protection circuit as claimed in claim 11, wherein the first pad is an input pad, and the second pad is a ground pad.
